(19) United States
(12) Patent Application Publication
(10) Pub. No.: US 2015/0103269 A1
(43) Pub. Date: Apr. 16, 2015

(54) TRANSPARENT CONDUCTIVE SUBSTRATE PRODUCTION METHOD, TRANSPARENT CONDUCTIVE SUBSTRATE, AND ELECTROSTATIC CAPACITANCE TOUCH PANEL

(71) Applicants: OSAKA UNIVERSITY, Suita-shi, Osaka (JP); SHOWA DENKO K.K., Minato-ku, Tokyo (JP)

(72) Inventors: Katsuaki Suganuma, Suita-shi (JP); Hiroshi Uchida, Minato-ku (JP); Kenji Shinozaki, Minato-ku (JP)

(73) Assignees: SHOWA DENKO K.K., Minato-ku, Tokyo (JP); OSAKA UNIVERSITY, Suita-shi, Osaka (JP)

(21) Appl. No.: 14/396,994

(22) PCT Filed: Apr. 26, 2013
(86) PCT No.: PCT/JP2013/062388

§ 371 Date: Oct. 24, 2014

(30) Foreign Application Priority Data
Apr. 26, 2012 (JP) 2012-101053

(51) Int. Cl. G06F 3/044; H05K 3/12; H05K 3/28; H05K 1/09

(52) U.S. Cl. CPC G06F 3/044; H05K 1/097; H05K 3/1208; H05K 3/1291; H05K 3/28; H05K 2201/0108
USPC 349/12; 174/257; 174/251; 427/559; 156/277

(57) ABSTRACT

Provided are a transparent conductive substrate production method for an electrostatic capacitance touch panel having a high pattern recognition property, by simple steps without using a vacuum process and a wet etching method, as well as a transparent conductive substrate and an electrostatic capacitance touch panel. An electrode drawing lead wiring pattern is formed on at least one main face of a transparent film using a conductive paste. An electrode pattern forming unit prints an electrode pattern with a transparent conductive pattern forming ink containing metal nanowires or metal nanoparticles so that the electrode pattern is connected to the electrode drawing lead wiring pattern, and dries the printed electrode pattern. The dried electrode pattern is subjected to pulsed light irradiation by a photoirradiation unit 18, to sinter the metal nanowires or the metal nanoparticles contained in the transparent conductive pattern forming ink.

### TECHNICAL FIELD

The present disclosure relates to a transparent conductive substrate production method, a transparent conductive substrate, and an electrostatic capacitance touch panel. In more detail, the present disclosure relates to a method for producing a transparent conductive substrate suitable for an electrostatic capacitance touch panel, a transparent conductive substrate for an electrostatic capacitance touch panel, and an electrostatic capacitance touch panel.

### BACKGROUND ART

As various electronic devices such as mobile phones, mobile terminals, personal computers, or the like, have become highly functional and diversified, recently used is an electronic device which has a light transmissive touch panel attached on the front face of its display panel. A person can switch the functions of such an electronic device by pressing the surface of the touch panel with his/her finger, a pen, etc., while viewing the display on the display panel on the back side through the touch panel.

As for such a touch panel, for example, an electrostatic capacitance touch panel is known, which has a transparent substrate on which a predetermined shaped transparent electrode pattern is formed in the X-direction, and similar transparent electrode pattern is formed in the Y-direction.

FIG. 9 and FIG. 10 are views explaining a conventional touch panel structure. FIG. 9 is a partial plan view explaining an electrode structure of an electrostatic capacitance touch panel. FIG. 10 is a partial enlarged view explaining an electrode pattern portion of an electrostatic capacitance touch panel.

Such an electrostatic capacitance touch panel 100 is used, for example, by being arranged on the display surface of a display unit of an electronic device, and has a substrate 102 made of a transparent material on which transparent electrode pattern is formed. For example, a known substrate 102 may be a transparent substrate made of a glass plate, etc., having transparency, on the surface of which the X-electrode 104 made of a transparent material is formed, and the Y-electrode 106 also made of a transparent material is formed in the direction perpendicular to the X-electrode 104. In this electrostatic capacitance touch panel 100, as shown in FIG. 9, the X-electrode 104 is connected to routing electrodes 108 and 110 provided on right and left sides of the substrate 102, and the Y-electrode 106 is connected to the side of electrode drawing lead wiring 112 formed on one side, for example, upper side, of the substrate 102. These X-electrode 104 and Y-electrode 106 are formed into predetermined electrode patterns, respectively. In this electrostatic capacitance touch panel 100, for example, the X-electrode 104 is formed as shown by the solid line in FIG. 10, whereas the Y-electrode 106 is formed as shown by the dotted line in FIG. 10. Further, in a generally known form, when one electrode, i.e., the X-electrode 104, and the other electrode, i.e., the Y-electrode 106 are viewed from the surface side, the X-electrode connection region 104a intersects the Y-electrode connection region 106a, and a small constant gap d is provided between the adjacent X-electrode 104 and Y-electrode 106 when viewed from the surface side.

In order to prevent difficulties in visual understanding of a display, a car navigation system, etc., the X and Y electrode patterns are respectively formed by laminated films in which a silicon oxide film is provided between a pair of upper and lower ITO films, and are provided with a light transmission property (refer to Patent Document 1).

In order to form a conductive pattern on such a transparent conductive film, for a conventional transparent conductive film made of a metal oxide material such as ITO, a method for subjecting the transparent conductive film formed on the substrate by a vacuum process to wet etching, is commonly used (refer to Patent Documents 2 to 4). Further, recently, a transparent conductive film using nanowires has been proposed, and in this case, the conductive pattern is also formed by a wet etching method (refer to Patent Document 5).

Therefore, it has been desired to directly forming a pattern by printing an ink composition containing silver nanoparticles on a mesh, or by subjecting an ink composition containing silver nanowires to inkjet printing, screen printing, gravure printing, flexo printing, and the like. However, in order to perform printing, a binder resin is necessary, and in order to maintain the transparent property, the amount of silver nanoparticles or silver nanowires to be used should be smaller. Accordingly, there are drawbacks that the binder resin used therein covers the silver nanoparticles or silver nanowires, and in the case of the silver nanowires, the conductivity is lost. When the binder resin is not used, there are drawbacks that the pattern cannot be kept during printing, or even if the pattern can be kept immediately after the printing, the pattern may be collapsed when the solvent contained in the ink composition is dried.

### PRIOR ARTS

### Patent Document

Patent Document 1: Japanese Unexamined Patent Publication (Kokai) No. 2008-310550

Patent Document 2: Japanese Unexamined Patent Publication (Kokai) No. 2000-67762

Patent Document 3: Japanese Unexamined Patent Publication (Kokai) No. 2003-57673

Patent Document 4: Japanese Patent No. 3393470

Patent Document 5: Japanese Unexamined Patent Publication (Kohyo) No. 2009-505358

### SUMMARY

One of the objectives of the present disclosure is to provide a preferable transparent conductive substrate production method for an electrostatic capacitance touch panel having a high pattern recognition property, by simple steps without using a vacuum process and a wet etching method, and to provide a transparent conductive substrate, and an electrostatic capacitance touch panel.

In order to attain the above objective, an embodiment of the present disclosure is a transparent conductive substrate production method comprising a step for printing an electrode drawing lead wiring pattern for an electrode by conductive paste at least on one of the main faces of a transparent substrate, an electrode printing step for printing an electrode pattern to be connected to the drawing lead wiring pattern for the electrode by a transparent conductive pattern forming ink which contains metal nanowires or metal nanoparticles, and a shape-holding material, an electrode drying step for drying the electrode pattern, and an electrode sintering step for sintering the metal nanowires or the metal nanoparticles by irradiating pulsed light to the electrode pattern which has been dried.

The transparent conductive substrate comprises a first electrode pattern, a second electrode pattern, and a transparent insulation layer, the transparent insulation layer is located between the first electrode pattern and the second electrode pattern, and the first electrode pattern and the second electrode pattern are formed by sintered metal.

Another embodiment of the present disclosure is an electrostatic capacitance touch panel wherein the transparent conductive substrate is provided on the front face of a display panel of an electronic device.

### BRIEF DESCRIPTION OF DRAWINGS

FIG. 1 is a view illustrating an example of production steps for a transparent conductive substrate according to the present embodiment.

FIG. 2 is a view illustrating the definition of pulsed light.

FIG. 3 is a view explaining a mesh pattern using metal nanoparticles.

FIG. 4 is a view illustrating a configuration example of a transparent conductive substrate for an electrostatic capacitance touch panel produced according to the production steps shown in FIG. 1.

FIG. 5 is a view illustrating another example of production steps for a transparent conductive substrate for an electrostatic capacitance touch panel.

FIG. 6 is a view illustrating a configuration example of a transparent conductive substrate for an electrostatic capacitance touch panel produced according to the production steps shown in FIG. 5.

FIG. 7 is a schematic view of a pattern (X-electrode pattern) of a transparent conductive substrate used in Example.

FIG. 8 is a schematic view of a pattern (Y-electrode pattern) of a transparent conductive substrate used in Example.

FIG. 9 is a view explaining a conventional touch panel structure.

FIG. 10 is a view explaining a conventional touch panel structure.

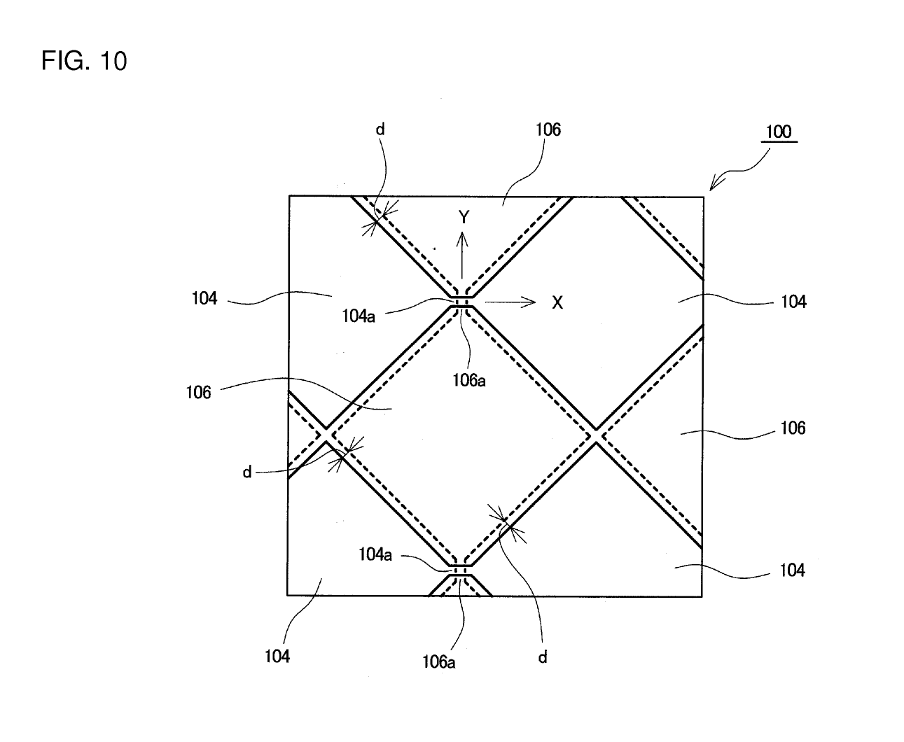

### EMBODIMENT

Hereinbelow, an exemplary embodiment of the present invention (hereinafter, referred to as an embodiment) will be described, with reference to the drawings. In the present specification, “transparent” of the transparent conductive substrate means the light transmittance of 65% or more within the visible light range (400 to 800 nm).

### (One Aspect of Disclosure)

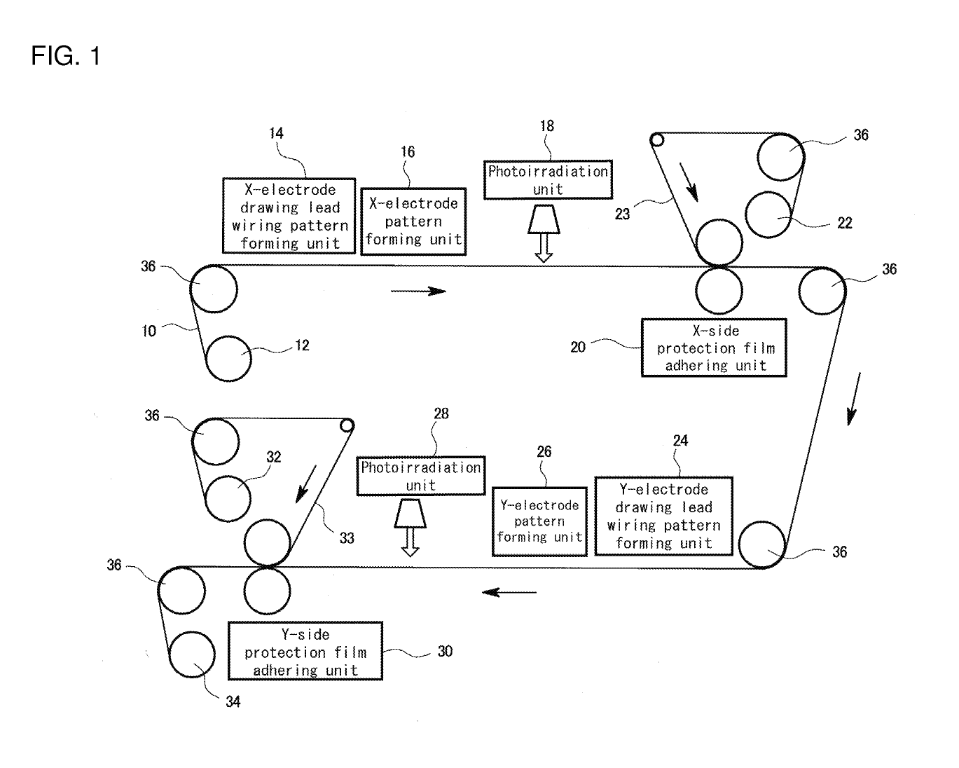

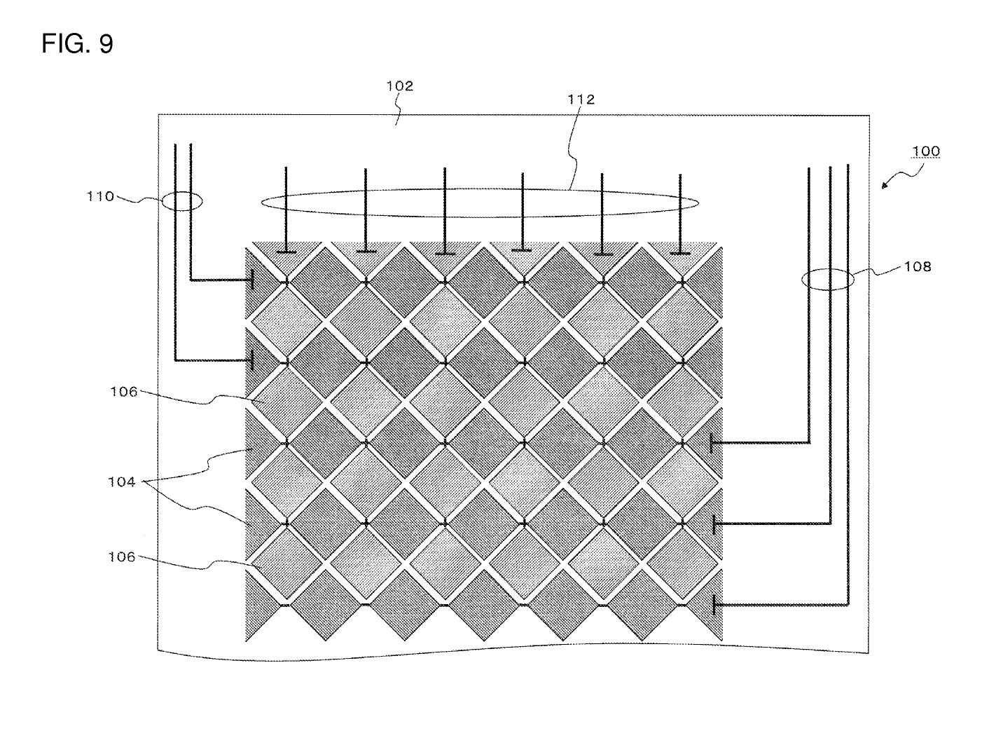

FIG. 1 shows an example of production steps of a transparent conductive substrate for an electrostatic capacitance touch panel according to an embodiment. In FIG. 1, while a transparent substrate (transparent film substrate) 10 is drawn from a substrate roll 12, an X-electrode drawing lead wiring pattern is formed on one main face of the transparent film substrate 10 by an electrode drawing lead wiring pattern forming unit 14 for the X-electrode (corresponding to the first electrode). The X-electrode electrode drawing lead wiring pattern is, for example, a pattern shown in FIG. 9. The X-electrode drawing lead wiring pattern forming unit 14 forms the X-electrode drawing lead wiring electrode pattern using a known conductive paste, by a printing method such as screen printing, gravure printing, flexo printing, and thereafter, dries the formed pattern. The drying method may be heating by an oven, heating by pulsed light irradiation, and the like.

On the main face of the transparent film substrate 10 where the X-electrode drawing lead wiring pattern has been formed, an X-electrode pattern is formed by the X-electrode pattern forming unit 16. The X-electrode pattern is formed to be connected to the X-electrode drawing lead wiring pattern. In order to adjust the positions of the X-electrode drawing lead wiring pattern and the X-electrode pattern, it is preferable to print an appropriate position adjustment mark by the X-electrode drawing lead wiring pattern forming unit 14. In the X-electrode pattern forming unit 16, an X-electrode pattern may be formed using a transparent conductive pattern forming ink in which metal nanowires or metal nanoparticles are dispersed in a dispersion medium containing a shape-holding material mentioned below. The above shape-holding material contains an organic compound having a molecular weight in the range from 150 to 500, and having a viscosity of 1.0×10³ to 2.0×10⁶ mPa·s at 25° C. Here, if the organic compound having the viscosity of the above range at 25° C. is liquid, the shape-holding material may be composed only by the organic compound. On the other hand, if the viscosity of the organic compound at 25° C. is higher than the above viscosity range, and the organic compound is solid at 25° C., the organic compound may be previously mixed (diluted, dissolved) with an appropriate solvent (a solvent capable of dissolving the organic compound, such as below-mentioned viscosity adjustment solvent, etc.) to prepare a liquid shape-holding material having a viscosity of the above mentioned range.

If the shape-holding material has a viscosity lower than the above range, the shape of the printed pattern cannot be maintained, whereas if the shape-holding material has a viscosity higher than the above range, bad influences such as occurrence of thread-forming property maybe caused at the time of printing. More preferably, the shape-holding material has a viscosity in the range of 5.0×10⁴ to 1.0×10⁶ mPa·s at 25° C.

If the organic compound contained in the shape-holding material to be used has a too large molecular weight, the shape-holding material cannot be efficiently removed at the time of sintering, and thus, the resistance cannot be decreased. Therefore, the molecular weight is 500 or lower, preferably 400 or lower, more preferably 300 or lower.

The X-electrode pattern forming unit 16 forms an X-electrode drawing lead wiring pattern using the above transparent conductive pattern forming ink, by a printing method such as screen printing, gravure printing, flexo printing, and dries the formed pattern using an oven, etc.

The X-electrode pattern formed by the X-electrode pattern forming unit 16 is subjected to pulsed light irradiation by a photoirradiation unit 18, to sinter the metal nanowires or the metal nanoparticles. Before the pulsed light irradiation performed for the purpose of sintering, the X-electrode pattern may be heated by oven heating or pulsed light irradiation to dry the solvent. Further, drying and sintering can be performed at the same time by pulsed light irradiation. The atmospheric temperature at the time of pulsed light irradiation is not limited, and the irradiation may be performed at a room temperature or at a heating atmosphere.

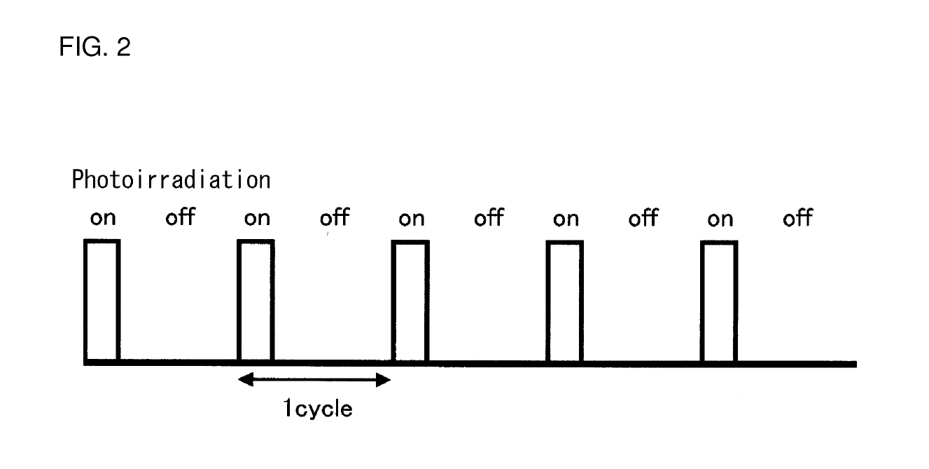

In the present specification, the “pulsed light” is a light having a short photoirradiation period (irradiation time). When a plurality of times of photoirradiation are repeated, as shown in FIG. 2, there is a period in which photoirradiation is not performed (irradiation interval (off)) between a first photoirradiation period (on) and a second photoirradiation period (on). In FIG. 2, the pulsed light is illustrated to have a constant light intensity, but the light intensity may vary within one photoirradiation period (on). The pulsed light is irradiated from a light source provided with a flash lamp such as a xenon flash lamp. Using such a light source, pulsed light is irradiated to metal nanowires or metal nanoparticles in the X-electrode pattern formed on the transparent film substrate 10. When irradiation is repeated for n-times, one cycle (on +off) in FIG. 2 is repeated for n-times. At the time of repeated irradiation, it is preferable to cool the transparent film substrate 10 side so that the substrate can be cooled to a temperature near the room temperature when the next pulsed light irradiation is performed.

For the pulsed light, electromagnetic waves having a wavelength in the range from 1 pm to 1 m may be used, preferably, electromagnetic waves having a wavelength in the range from 10 nm to 1000 μm may be used (from far ultraviolet to far infrared), and more preferably, electromagnetic waves having a wavelength in the range from 100 nm to 2000 nm may be used. Examples of such electromagnetic wave may be gamma rays, X-rays, ultraviolet rays, visible rays, infrared rays, microwaves, radiowaves on the longer wavelength side of the microwaves, and the like. Considering transformation into thermal energy, too short wavelength is not preferable because the transparent film substrate 10 and each electrode pattern may be largely damaged. Also, too long wavelength is not preferable because efficient absorption and exothermic heating cannot be performed. Accordingly, the wavelength range is preferably the range from the ultraviolet to infrared among the above-mentioned wavelengths, and more preferably, in the range from 100 to 2000 nm.

One irradiation period (on) of the pulsed light is preferably from 20 microseconds to 50 milliseconds, although the period may vary depending on the light intensity. If the period is less than 20 microseconds, sintering of the metal nanowires or the metal nanoparticles does not progress, resulting in providing a lower effect of increasing the performance of a conductive pattern. If the period is longer than 50 milliseconds, there may be bad influences on the substrate due to photodegradation and thermal degradation, and further, nanowires or metal nanoparticles may be easily blown away. More preferably, the irradiation period is from 40 microseconds to 10 milliseconds. Due to the reasons mentioned above, pulsed light instead of continuous light is used in the present embodiment. A single shot of the pulsed light is effective, but the irradiation may be repeated as mentioned above. When the irradiation is repeated, the irradiation interval (off) is preferably in a range from 20 microseconds to 5 seconds, and more preferably in a range from 2000 microseconds to 2 seconds. If the irradiation interval is shorter than 20 microseconds, the pulsed light becomes similar to a continuous light and another irradiation is performed after one irradiation without leaving enough time for cooling. Thus, the substrate is heated to a very high temperature and is deteriorated. The irradiation interval longer than 5 seconds is not preferable in view of the productivity because the processing time becomes long.

A transparent protection film 23 drawn from a protection film roll 22 is adhered on the surface of the transparent film substrate 10 on which the X-electrode routing electrode pattern and the X-electrode pattern are formed, by an X-side protection film adhering unit 20. Instead of adhering the transparent protection film 23, an overcoat resin may be printed and cured to cover the X-electrode drawing lead wiring pattern and the X-electrode pattern.

The overcoat resin used herein may be a liquid resin composition in which a photopolymerization initiator is added to multifunctional acrylate, epoxy acrylate, urethane acrylate, etc.

The multifunctional acrylate may be (meth)acrylic esters of polyhydric alcohols, the polyhydric alcohols being, for example, dipentaerythritol, pentaerythritol, ditrimethylolpropane, trimethylolpropane, ethylene glycol, propylene glycol, 1,4-butanediol, 1,6-hexanediol, 1,8-octanediol, diethylene glycol, triethylene glycol, dipropylene glycol, 1,6-hexane dimethanol, etc.

The epoxy acrylate is a reactant obtained by, for example, adding a (meth)acrylic acid to the oxirane ring of an epoxy resin. The epoxy resin used herein may be bisphenol A epoxy resin, bisphenol F epoxy resin, novolak epoxy resin, etc.

The urethane acrylate is obtained by the reaction using, for example, hydroxyalkyl(meth)acrylate and polyisocyanate, and if necessary, polyol. Specific examples of hydroxyalkyl(meth)acrylate may be hydroxymethyl(meth)acrylate, mono(meth)acrylate of 1,4-butanediol, and mono(meth)acrylate of cyclohexandimethanol. Specific examples of polyisocyanate may be isophorone diisocyanate, TDI (tolylene diisocyanate), MDI (methylene diphenyl diisocyanate), hydrogenated MDI, etc. Specific examples of polyol may be polyethylene glycol having a molecular weight of approximately 500 to 1000, polypropylene glycol, poly(1,4-butanediol), polyester polyol, polycarbonate diol, polybutadiene having hydroxyl groups at both terminals, polyisoprene having hydroxyl groups at both terminals, etc. The polyester polyol is a polyester of a dicarboxylic acid such as a butyric acid, an adipic acid, etc., with 1,3-butanediol, 2-methyl-1,3-propanediol, 1,6-hexanediol, cyclohexanedimethanol, etc. The polycarbonate diol is an ester of a carbonic acid with 1,4-butanediol, 1,6-hexanediol, cyclohexanedimethanol, etc.

The photopolymerization initiator may be a radical polymerization initiator or a cationic polymerization initiator. The radical polymerization initiator may be a carbonyl compound such as, for example, acetophenone, 2,2-dimethoxy-2-phenylacetophenone, 2,2-diethoxyacetophenone, 4′-isopropyl-2-hydroxy-2-methylpropiophenone, 2-hydroxy-2-methylpropiophenone, 4,4′-Bis(diethylamino)benzophenone, benzophenone, methyl(o-benzoyl)benzoate, 1-phenyl-1,2-propanedione-2-(o-ethoxycarbonyl)oxime, 1-phenyl-1,2-propanedione-2-(o-benzoyl)oxime, benzoin, benzoin methyl ether, benzoin ethyl ether, benzoin isopropyl ether, benzoin isobutyl ether, benzoin octyl ether, benzyl, benzyl dimethyl ketal, benzyl diethyl ketal, diacetyl, etc., an anthraquinone or thioxanthone derivative such as methylanthraquinone, chloroanthraquinone, chlorothioxanthone, 2-methylthioxanthone, 2-isopropylthioxanthone, etc., a sulfur compound such as diphenyl disulfide, dithiocarbamate, etc.

The cationic photopolymerization initiator may be a diazonium salt of Lewis acid, an iodonium salt of Lewis acid, a sulfonium salt of Lewis acid, a phosphonium salt of Lewis acid, etc. Specific examples may be triphenylsulfonium hexafluorophosphonate, triphenylsulfonium hexafluoroantimonate, diphenyliodonium hexafluorophosphonate, diphenyliodonium hexafluoroantimonate, N,N-diethylamino phenyldiazonium hexafluorophosphonate, p-methoxy phenyldiazonium fluorophosphonate, etc.

An overcoat resin is provided on the X-electrode drawing lead wiring pattern and the X-electrode pattern by a known printing method such as screen printing, gravure printing, flexo printing, etc., and the printed resin is cured, to thereby form a protection layer. Curing can be performed in a short time by the above-mentioned pulsed light irradiation.

Next, the transparent film substrate 10 on which the X-electrode drawing lead wiring pattern and the X-electrode pattern are formed, is moved to the position where the electrode drawing lead wiring pattern forming unit 24 for the Y-electrode (corresponding to the second electrode). A Y-electrode drawing lead wiring pattern is formed on the main face different from the main face where the X-electrode drawing lead wiring pattern and the X-electrode pattern are formed, by the Y-electrode drawing lead wiring pattern forming unit 24. The Y-electrode drawing lead wiring pattern is, for example, a pattern shown in FIG. 9. The Y-electrode drawing lead wiring pattern forming unit 24 forms a Y-electrode drawing lead wiring pattern using a known conductive paste, by a printing method such as screen printing, gravure printing, flexo printing, and dries the formed pattern.

On the main face of the transparent film substrate 10 where the Y-electrode drawing lead wiring pattern has been formed, a Y-electrode pattern is formed by the Y-electrode pattern forming unit 26. The Y-electrode pattern is formed to be connected to the Y-electrode drawing lead wiring pattern. In order to adjust the positions of the Y-electrode drawing lead wiring pattern and the Y-electrode pattern, it is preferable to print an appropriate position adjustment mark by the Y-electrode drawing lead wiring pattern forming unit 24. The Y-electrode pattern forming unit 26 also uses a transparent conductive pattern forming ink containing metal nanowires or metal nanoparticles, and a shape-holding solvent, to form the Y-electrode pattern. Here, the shape-holding material is a solvent having the above-mentioned molecular weight and viscosity. The Y-electrode pattern forming unit 26 form the Y-electrode pattern using the above transparent conductive pattern forming ink, by a printing method such as screen printing, gravure printing, flexo printing, and dries the formed pattern.

The Y-electrode pattern formed by the Y-electrode pattern forming unit 26 is subjected to pulsed light irradiation by a photoirradiation unit 28, to sinter the metal nanowires or the metal nanoparticles. Before or at the same time of the pulsed light irradiation, the Y-electrode pattern may be heated an appropriate method.

A transparent protection film 33 drawn from a protection film roll 32 is adhered on the surface of the transparent film substrate 10 on which the Y-electrode drawing lead wiring pattern and the Y-electrode pattern are formed, by a Y-side protection film adhering unit 30. Instead of adhering the transparent protection film 33, an overcoat resin may be printed and cured to cover the Y-electrode drawing lead wiring pattern and the Y-electrode pattern. The overcoat resin used here is the same as those applicable to the X-electrode drawing lead wiring pattern and the X-electrode pattern.

As mentioned above, the transparent film substrate 10 provided on opposite sides thereof with the X- and Y-electrode drawing lead wiring patterns and the X- and Y-electrode patterns is wound around the winding roll 34, and a series of roll-to-roll step is complete.

The X-electrode drawing lead wiring pattern forming unit 14 and the X-electrode pattern forming unit 16 may be arranged in reverse order, and also, the Y-electrode drawing lead wiring pattern forming unit 24 and the Y-electrode pattern forming unit 26 may be arranged in reverse order. In this case, the above-mentioned position adjustment marks are printed by the X-electrode pattern forming unit 16 and the Y-electrode pattern forming unit 26, respectively. Further, when metal nanoparticles are used in the transparent conductive pattern forming ink, higher conductivity can be obtained compared to the case where metal nanowires are used, because the content of the nanoparticles in the ink composition can be larger than the content of the nanowires. Therefore, it is possible to use the transparent conductive pattern forming ink containing metal nanoparticles in both of the electrode pattern forming step and electrode drawing lead wiring pattern forming step, and perform the two steps at the same time. The X-side protection film adhering unit 20 may be arranged after the photoirradiation unit 28 (for example, before the Y-side protection film adhering unit 30).

In the example of FIG. 1, the progressing directions of the transparent film substrate 10 and the transparent protection films 23 and 33 are changed by an appropriate number of direction change rollers 36, but this is an example for easy explanation, and the present disclosure is not limited thereto. In accordance with the arrangement of each structural component, the directions of the transparent film substrate 10 and the transparent protection films 23 and 33 may be appropriately determined.

The organic compound contained in the shape-holding material is preferably a compound containing a hydroxyl group, and for example, monosaccharides, polyol, or a compound having a quaternary carbon atom, and/or a compound having an alkyl group comprising a bridged carbon cyclic structure and a hydroxyl group, is preferable. For example, diglycerine, 2,2,4-trimethyl-1,3-pentanediolmonoisobutyrate, 2,2,4-trimethyl-1,3-pentanediol diisobutyrate, xylulose, ribulose, bornylcyclohexanol, bornylphenol, isobornylcyclohexanol, isobornylphenol, etc., may be exemplified.

Among the above listed compounds, a compound having an isobornyl group and a hydroxyl group is particularly preferable. Not only the complicated steric structure of the isobornyl group, but also the hydrogen bond of the hydroxyl group, apply an appropriate viscosity to the ink. Further, a compound having an isobornyl group and a hydroxyl group has a high viscosity although the volatilization temperature is not very high, resulting in providing a transparent conductive pattern forming ink having a high viscosity. As a compound having an isobornyl group and a hydroxyl group, either one or both of isobornyl cyclohexanol or isobornylphenol maybe exemplified. The above listed compounds have an appropriate viscosity, and may apply an appropriate viscosity to the transparent conductive pattern forming ink. Further, because the compound has an appropriate boiling point as an ink solvent, the residual may be reduced during appropriate heating, photosintering, after the completion of printing and drying. The content of the shape-holding material in the ink is preferably 10 to 90% by mass relative to the total mass of the dispersion medium, and is more preferably 30 to 80% by mass. If the content of the shape-holding material is less than 10% by mass, the transparent conductive pattern forming ink cannot have an appropriate viscosity, and printing cannot be performed. If the content of the shape-holding material exceeds 90% by mass, the viscosity of the transparent conductive pattern forming ink is too high cause worse thread-forming property at the time of printing, and printing may not be performed.

It is desired that the shape-holding material itself is a viscous liquid having a viscosity in the above range. However, other viscosity adjustment solvent may be mixed to satisfy the above viscosity range, and to prepare a dispersion medium having a viscosity in the above range, and thereby, the transparent conductive pattern forming ink may be provided by dispersing metal nanowires and/or metal nanoparticles as conductive components in the dispersion medium.

The viscosity adjustment solvent may be, for example, water, alcohol, ketone, ester, ether, hydrocarbon solvents and aromatic hydrocarbon solvents. In order that each component in the ink composition can be well dispersed, a preferable viscosity adjustment solvent may be water, ethanol, isopropyl alcohol, 1-methoxy-2-propanol (PGME), ethylene glycol, diethylene glycol, triethylene glycol, dipropylene glycol, ethylene glycol monomethyl ether, ethylene glycol monoethyl ether, ethylene glycol monopropyl ether, diacetone alcohol, ethylene glycol monobutyl ether, propylene glycol, diethylene glycol monomethyl ether, diethylene glycol monoethyl ether, dipropylene glycol monopropyl ether, diethylene glycol monobutyl ether, tripropylene glycol, triethylene glycol monoethyl ether, terpineol, dihydroterpineol, dihydroterpinyl monoacetate, methyl ethyl ketone, cyclohexanone, ethyl lactate, propylene glycol monomethyl ether acetate, diethylene glycol monomethyl ether acetate, diethylene glycol monobutyl ether acetate, ethylene glycol monomethyl ether acetate, ethylene glycol monobutyl ether acetate, dibutyl ether, octane, or toluene, and among them, terpineol is particularly preferable. Each solvent may be used by itself, but two or more kinds of the solvents may be mixed.

The metal nanowire and the metal nanoparticle are metal having a diameter of the wire or an outer diameter of the particle in the order of nanometer, and are conductive materials. The metal nanowire has a wire shape (including a hollow tube shape), and the metal nanoparticle has a granular shape. They may be soft or rigid. Either metal nanowires or metal nanotubes may be used, but they may be mixed. The metal nanowires and the metal nanotubes may contain a metal oxide in at least a part thereof.

The kind of the metal may be one selected from the group consisting of gold, silver, platinum, copper, nickel, iron, cobalt, zinc, ruthenium, rhodium, palladium, cadmium, osmium, and iridium, or an alloy etc., formed by combining from these. In order to obtain a coating film having a low surface resistance and a high total light transmittance, containing at least one of gold, silver, and copper is preferable. These metals have a high conductivity, and thus, when a certain surface resistance should be obtained, the density of the metal within the surface may be reduced, and high total light transmittance can be achieved.

Among these metals, containing at least gold or silver is preferable. The most appropriate example may be the silver nanowire.

The metal nanowires in the transparent conductive pattern forming ink preferably show certain distributions regarding their diameter sizes, major axis lengths, and aspect ratios. The distributions are selected so that the coating film obtained by the transparent conductive pattern forming ink according to the present embodiment has a high total light transmittance and a low surface resistance. Specifically, the metal nanowires have an average diameter size of preferably 1 nm or more and 500 nm or less, more preferably 5 nm or more and 200 nm less, still more preferably 5 nm of more and 100 nm or less, and particularly preferably 10 nm or more and 100 nm or less. The average major axis length of the metal nanowires is preferably 1 μm or more and 100 μm or less, more preferably 1 μm or more and 50 μm or less, still more preferably2 μm or more and 50 μm or less, and particularly preferably 5 μm or more and 30 μm or less. While satisfying the above average diameter size and the average major axis length, the metal nanowires have an average aspect ratio of preferably 10 or more, more preferably 100 or more, and still more preferably 200 or more. Here, the aspect ratio refers to a value obtained by a/b, wherein “b” represents an average diameter size of the metal nanowires and “a” represents an average major axis length thereof. The values “a” and “b” may be measured by a scanning electron microscope. By controlling the concentration of the metal nanowires in the transparent conductive pattern forming ink and maintaining the conductivity by the inter-locking of the wires, the transparent conductive pattern can be formed.

With respect to the content of the metal nanowires in the transparent conductive pattern forming ink containing metal nanowires is 0.01 to 10% by mass, and more preferably 0.05 to 2% by mass, relative to the total mass of the transparent conductive pattern forming ink, from the viewpoints of preferable dispersion property of each component, preferable pattern forming property of the coating film obtained by the transparent conductive pattern forming ink, high conductivity, and a preferable optical property. If the metal nanowires are contained less than 0.01% by mass, a very thick transparent conductive pattern should be printed in order to ensure a desired conductivity, and thus, the degree of difficulty in printing increases, and maintaining the pattern during drying becomes difficult. If the content of the nanowires exceeds 10% by mass, the printing must be performed very thin in order to ensure a desired transparency, and the printing is also difficult. When the metal nanowires are used, the content must be smaller compared to the case where the below-mentioned metal nanoparticles are used, in order to maintain the transparency.

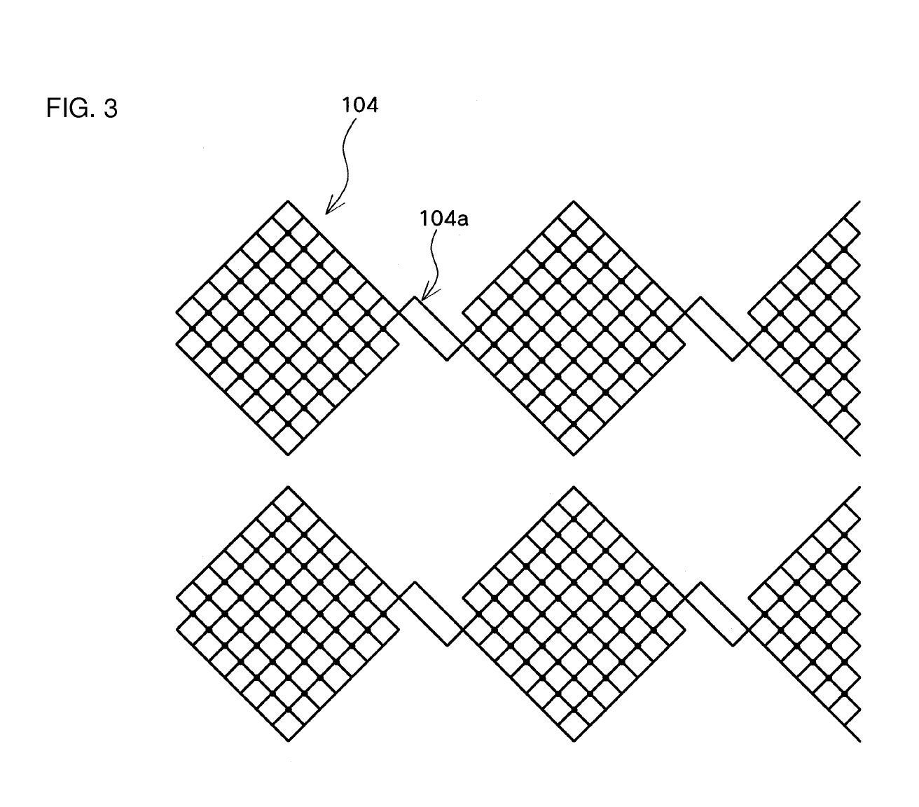

When metal nanoparticles are used, spherical particles are preferable. When the metal nanoparticles are used, particles should be in contact to each other in order to obtain the conductivity, but if the pattern in which the metal nanoparticles are provided on a whole surface is printed, transparency cannot be obtained. Therefore, when the metal nanoparticles are used, as shown in FIG. 3, the X-electrode 104 and its connection region 104a are printed in mesh form to maintain the transparency. The same is true for the Y-electrode 106 and its connection region 106a.

In this case, the line width of the mesh is preferably 10 μm or less, and the space between the lines should be at least 3 times, and preferably 10 times of the line width. In order to print a mesh having a small line width, the diameter of the nanoparticle is at least 3 μm or less, preferably 1 μm or less, and more preferably 500 nm or less. Here, the particle diameter refers to a median diameter (D50) which is obtained by measuring diameters using a particle diameter distribution measurement device by a dynamic light scattering method, specifically, Nanotrac UPA-150 (a dynamic light scattering method) manufactured by Nikkiso Co., Ltd, and performing spherical approximation.

In the transparent conductive pattern forming ink containing metal nanoparticles, the dispersion medium is used in an amount of 1 to 50 parts by mass, preferably 3 to 20 parts by mass, relative to 100 parts by mass of the metal nanoparticles. Compared to the case where the above-mentioned metal nanowires are used, higher content of the metal nanoparticles are mixed, and thus, a film having a lower resistance can be obtained. Therefore, although the electrode pattern is printed in the form of a thin mesh, the obtained properties are almost same as the case where the transparent conductive pattern forming ink containing metal nanowires is printed over the entirety.

When the metal nanoparticles are used, a binder resin instead of the above-mentioned shape-holding material may be used in the dispersion medium. The binder resin may be a thermoplastic resin or a thermoset resin, which is, for example, a poly-N-vinyl compound such as polyvinylpyrrolidone, polyvinyl caprolactone, a polyalkylene glycol compound such as polyethyleneglycol, polypropyleneglycol, poly THF, polyurethane, a cellulose compound and a derivative thereof, an epoxy compound, a polyester compound, chlorinated polyolefin, and a polyacrylic compound. Among them, polyvinylpyrrolidone is preferable in view of the binder effect.

The transparent conductive pattern forming ink may contain other components such as a reducing agent, etc., in accordance with needs. When a metal which can be easily oxidized, such as copper, etc., or a metal oxide is used, mixing a reducing agent is preferable. The reducing agent which can be used, may be an alcohol compound, such as methanol, ethanol, isopropyl alcohol, butanol, cyclohexanol, and terpineol; polyhydric alcohol, such as ethylene glycol, propylene glycol, and glycerin; a carboxylic acid, such as formic acid, acetic acid, oxalic acid, and succinic acid; a carbonyl compound, such as acetone, methyl ethyl ketone, benzaldehyde, and octyl aldehyde; an ester compound, such as ethyl acetate, butyl acetate, and phenyl acetate; and a hydrocarbon compound, such as hexane, octane, cyclohexane, toluene, naphthalene, and decalin. Among those mentioned above, polyhydric alcohol, such as ethyleneglycol, propyleneglycol, glycerin and the like, and carboxylic acid, such as formic acid, acetic acid, and oxalic acid are preferable in view of the efficiency of a reducing agent. Polyethyleneglycol and propyleneglycol which are classified as polyhydric alcohol are preferable because they can also function as a binder resin.

The transparent film substrate 10 may be rigid or easily bent, and may be colored, but is preferably has high light transmittance and a low haze value. Therefore, the material for the transparent film substrate 10 may be, for example, inorganic glass, polyimide, polycarbonate, polyether sulfone, acryloyl, polyester (polyethylene terephthalate, polyethylene naphthalate, etc.), polyolefin, polyvinyl chloride, alicyclic hydrocarbon, etc. A polyester film such as polyethylene terephthalate, polyethylene naphthalate, a polycarbonate film, an acryloyl film such as polymethyl methacrylate, a transparent polyimide film using an alicyclic material, inorganic glass, may be more preferable. In particular, since the roll-to-roll processing is performed, the use of a polyester film is desired.

With respect to the thickness of the transparent film substrate 10, if the thickness too small, there may be drawbacks regarding the strength at the coating step and size stability during drying, whereas if the thickness is too large, performing the roll-to-roll step becomes difficult. Therefore, the thickness is preferably 12 μm to 500 μm, and more preferably, 25 μm to 188 μm. In order to improve the adhesive property of the surface, an easy adhesion treatment may be performed, and as far as the transparency is maintained, a corona treatment or a plasma treatment may be performed.

The transparent protection films 23 and 33 may be a film formed by coating an adhesive layer on the material of the transparent film substrate 10.

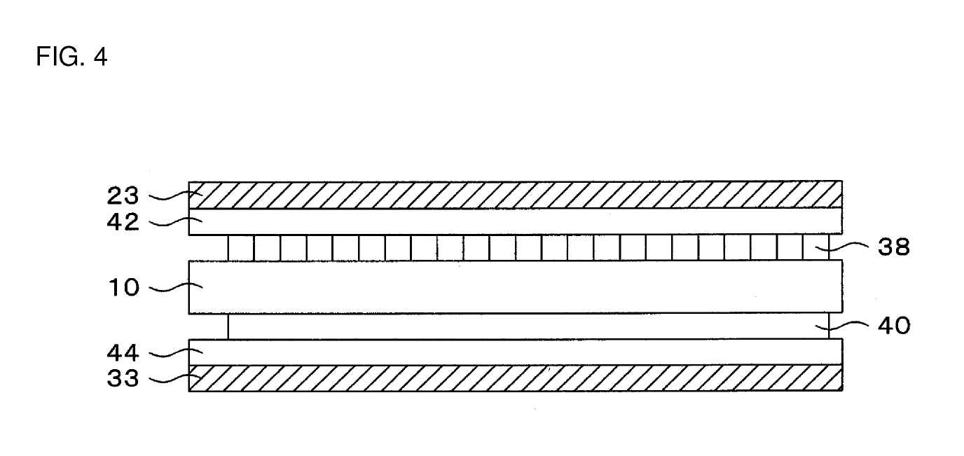

FIG. 4 shows a configuration example of a transparent conductive substrate for an electrostatic capacitance touch panel produced according to the production steps shown in FIG. 1. In FIG. 4, the X-electrode pattern 38 and the Y-electrode pattern 40 are formed on different main faces, which are upper and lower main faces in the example of FIG. 4, of the transparent film substrate 10 (corresponding to the transparent insulation layer). In FIG. 4, the X-electrode drawing lead wiring pattern and the Y-electrode drawing lead wiring pattern are not shown. The surfaces of the transparent film substrate 10 on which the X-electrode pattern 38 and the Y-electrode pattern 40 are formed, are respectively covered with transparent protection films 23 and 33 which are attached (adhered) by adhesive layers 42 and 44. For the transparent protection film, for example, PANAPROTECT (registered trademark) PX50T01A15 (PET film (50 μm thick) provided with a 15 μm-thick adhesive layer on one side, manufactured by PANAC Co., Ltd.) may be used.

### (Another Aspect of the Disclosure)

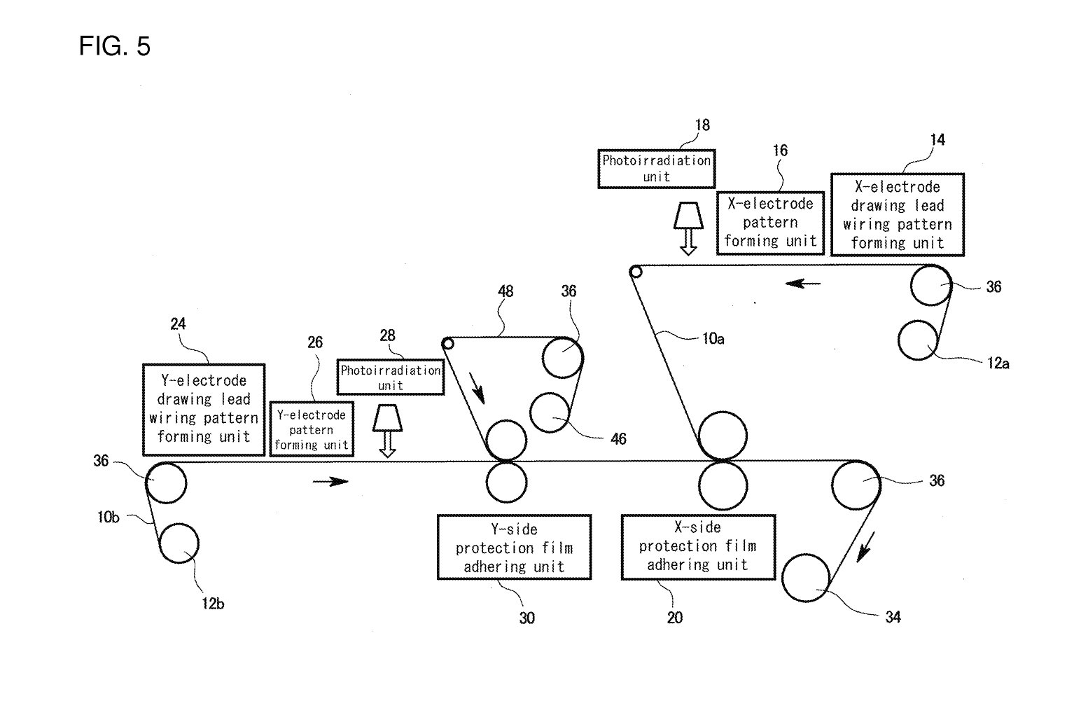

FIG. 5 illustrates another example of the production steps of a transparent conductive substrate for an electrostatic capacitance touch panel. In FIG. 5, the same numerals are assigned to the same elements shown in FIG. 1. In the example of FIG. 5, while a first transparent film substrate 10a is drawn from a first substrate roll 12a, an X-electrode (corresponding to the first electrode) routing electrode pattern forming unit 14 forms a X-electrode routing electrode pattern on one main face of the first transparent film substrate 10a, and dries the formed pattern.

On the main face of first transparent film substrate 10a on which the X-electrode drawing lead wiring pattern has been formed, an X-electrode pattern forming unit 16 forms an X-electrode pattern using the transparent conductive pattern forming ink. The X-electrode pattern is formed to be connected to the X-electrode drawing lead wiring pattern. In order to adjust the positions of the X-electrode drawing lead wiring pattern and the X-electrode pattern, printing an appropriate position adjustment mark by the X-electrode drawing lead wiring pattern forming unit 14 is preferable.

The X-electrode pattern formed by the X-electrode pattern forming unit 16 is subjected to the pulsed light irradiation by a photoirradiation unit 18 to sinter the metal nanowires or the metal nanoparticles. Before the pulsed light irradiation for the purpose of sintering, the pulsed light may be used for heating the X-electrode pattern and drying the solvent. Further, drying and sintering may be performed at the same time by the pulsed light irradiation. The atmospheric temperature at the time of pulsed light irradiation is not limited, and the irradiation may be performed at a room temperature or at a heating atmosphere.

Further, while a second transparent film substrate 10b is drawn from a second substrate roll 12b, an Y-electrode (corresponding to the second electrode) drawing lead wiring pattern forming unit 24 forms a Y-electrode drawing lead wiring pattern on one main face of the second transparent film substrate 10b, and dries the formed pattern.

On the main face of second transparent film substrate 10b on which the Y-electrode drawing lead wiring pattern has been formed, an Y-electrode pattern forming unit 26 forms an Y-electrode pattern using the transparent conductive pattern forming ink. The Y-electrode pattern is formed to be connected to the Y-electrode drawing lead wiring pattern. In order to adjust the positions of the Y-electrode drawing lead wiring pattern and the Y-electrode pattern, printing an appropriate position adjustment mark by the Y-electrode drawing lead wiring pattern forming unit 24 is preferable.

The Y-electrode pattern formed by the Y-electrode pattern forming unit 26 is subjected to the pulsed light irradiation by a photoirradiation unit 28 to sinter the metal nanowires or the metal nanoparticles. Before the pulsed light irradiation for the purpose of sintering, the pulsed light may be used for heating the Y-electrode pattern and drying the solvent. Further, drying and sintering may be performed at the same time by the pulsed light irradiation.

On the surface of the second transparent film substrate 10b on which the Y-electrode drawing lead wiring pattern and the Y-electrode pattern are formed, a transparent protection film 48 drawn from a protection film roll 46 is adhered by a Y-side protection film adhering unit 30.

On the surface of the first transparent film substrate 10a on which the X-electrode drawing lead wiring pattern and the X-electrode pattern are formed, a transparent protection film 48 is adhered by an X-side protection film adhering unit 20. In this case, the first transparent film substrate 10a is adhered on one surface of the transparent protection film 48, and the second transparent film substrate 10b is adhered on the other surface, i.e., the opposite surface, of the transparent protection film 48. As a result, the first transparent film substrate 10a and the second transparent film substrate 10b are arranged (stacked) while the X-electrode pattern and the Y-electrode pattern are opposed to each other, with the transparent protection film 48 (corresponding to the third transparent film) therebetween.

The first transparent film substrate 10a and the second transparent film substrate 10b arranged with the transparent protection film 48 therebetween as mentioned above, are wound around a winding roll 34, and a series of roll-to-roll step is complete.

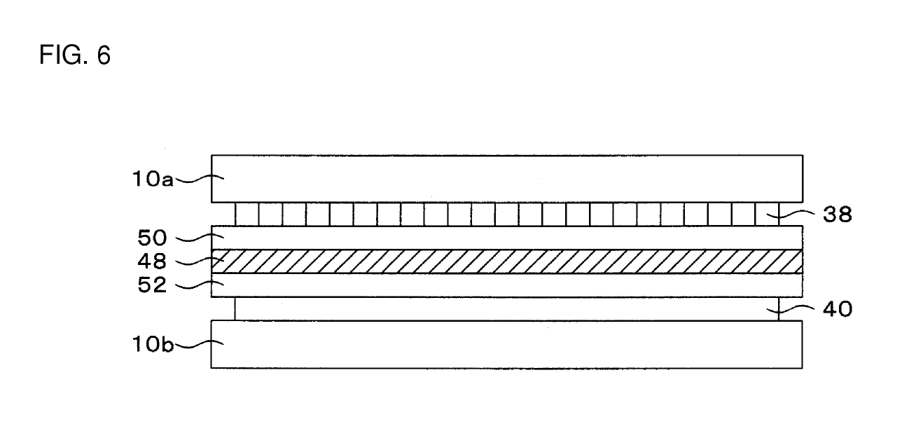

FIG. 6, shows another configuration example of a transparent conductive substrate for an electrostatic capacitance touch panel produced according to the production steps shown in FIG. 5. An X-electrode pattern 38 and a Y-electrode pattern 40 are respectively formed on one face of a first transparent film substrate 10a and a second transparent film substrate 10b, namely, in the example of FIG. 6, the lower face of the first transparent film substrate 10a and the upper face of the second transparent film substrate 10b. In FIG. 6, the X-electrode drawing lead wiring pattern and the Y-electrode drawing lead wiring pattern are not shown. The transparent protection film 48 is adhered by adhesive layers 50 and 52 on the face of the first transparent film substrate 10a on which the X-electrode pattern 38 is formed, and on the face of the second transparent film substrate 10b on which the Y-electrode pattern 40 is formed. The first transparent film substrate 10a and the second transparent film substrate 10b are arranged so that the X-electrode pattern 38 and the Y-electrode pattern 40 are opposed to each other with the transparent protection film 48 therebetween. In the present embodiment, the transparent protection film 48 provided with the adhesive layers 50 and 52 corresponds to the transparent insulation layer.

By providing the transparent conductive substrate exemplified by the above first and second embodiments, on the front face of a display panel of an electronic device, an electrostatic capacitance touch panel can be obtained.

### EXAMPLES

Hereinafter, specific examples of the present disclosure will be explained. The examples are described below for the purpose of easy understanding of the present disclosure, and the present disclosure is not limited to these examples.

### REFERENCE EXAMPLE

1. Preparation of Silver Nanowire Ink

### (Production of Silver Nanowire)

Polyvinylpyrrolidone K-90 (manufactured by Nippon Shokubai Co., Ltd.) (0.049 g), AgNO₃ (0.052 g), and FeCl₃ (0.04 mg) were dissolved in ethylene glycol (12.5 ml), and were heated and reacted at 150° C. for one hour. The resulting precipitate was isolated by centrifugal separation, and dried to obtain silver nanowires.

The above-mentioned ethylene glycol, AgNO₃, and FeCl₃ were manufactured by Wako Pure Chemical Industries, Ltd.

### (Production of Transparent Conductive Pattern Forming Ink)

Dibutyl ether was added to the above reaction solution of the silver nanowires heated and reacted at 150° C. for one hour, the volume of the added dibutyl ether being 6 times of the volume of the reaction solution. The mixture was stirred, and thereafter, left to stand, to settle out the nanowires. After the nanowires were settled out, the supernatant liquid was separated by decantation, and a silver nanowire suspension containing about 20% by mass of silver nanowires dispersed in dibutyl ether was obtained.

L-α-terpineol was added to this silver nanowire suspension, the added the L-α-terpineol having almost the same volume as the suspension, and dispersed well. Then, Tersorb MTPH (isobornyl cyclohexanol, manufactured by Nippon Terpene Chemicals, Inc.) was added as a shape-holding material, the volume of the added Tersorb MTPH being 2.33 time of the volume of L-α-terpineol, and dispersed well using ARV-310 manufactured by Thinky Corporation to thereby obtain transparent conductive pattern forming ink.

The concentration of the silver nanowire according to the Tg-DTA analysis was 2% by mass . For the Tg-DTA analysis, a differential high temperature thermal balance TG-DTA galaxy(S) manufactured by Bruker AXS GmbH was used, and the residual after heating at 500° C. was determined as the mass of the silver nanowires.

### (Production of Transparent Conductive Substrate)

### Example 1

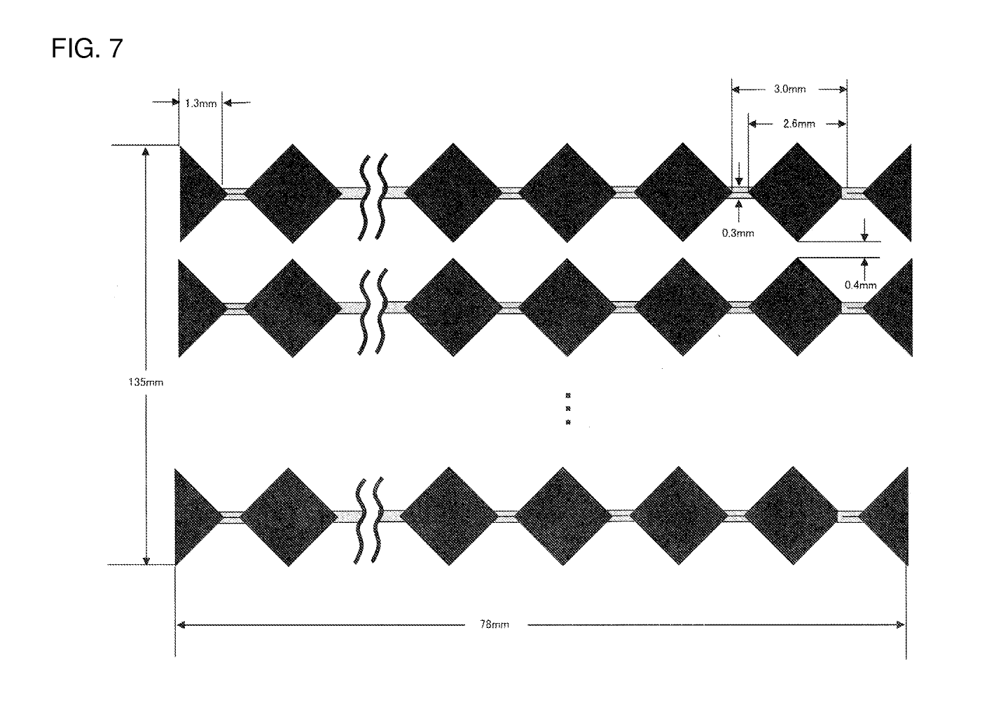

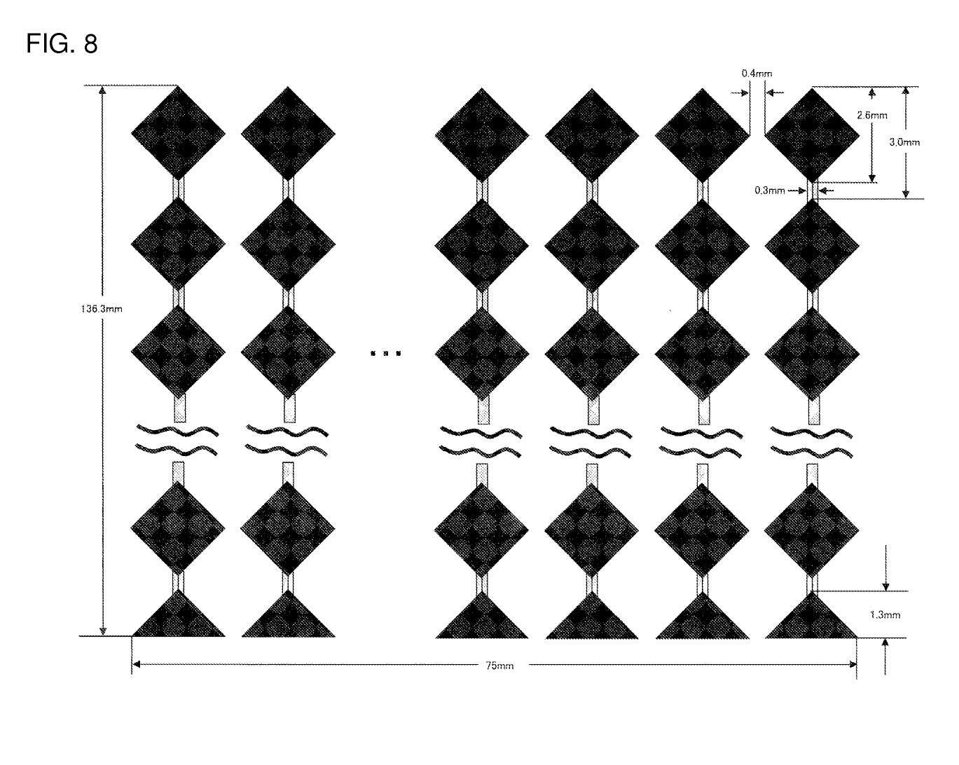

A transparent conductive substrate having the patterns shown in FIG. 7 and FIG. 8 was produced according to the following steps. In the pattern of FIG. 7, 25 rhombi (45-degree inclined square) are connected by connection regions in the lateral direction in the figure with a triangle, i.e., half of the rhombus, provided on each of the opposite ends of the connected rhombi to define a line, and 45 lines are juxtaposed in the upper/lower direction in the figure, the lines are not electrically connected with each other in the upper/lower direction. In the pattern of FIG. 8, 45 rhombi are connected by connection regions in the vertical (upper/lower) direction in the figure with a triangle, i.e., half of the rhombus, provided on one end (in FIG. 8, the lower end) of the connected rhombi to define a line, and 25 lines are juxtaposed in the lateral direction in the figure, the lines are not electrically connected with each other in the lateral direction.

First, the X-electrode drawing lead wiring pattern is printed on the surface of Lumirror (registered trademark) U48 (biaxially oriented polyester film, manufactured by Toray Industries, Inc., thickness 125 μm) using a silver paste CA-T30 (purchased from Daiken Chemical Production and Sales K.K.), and the printed pattern was subjected to drying at 120° C. Next, the transparent conductive pattern forming ink containing silver nanowires prepared in Reference Example, was used to print the X-electrode pattern shown in FIG. 7, and the printed pattern was subjected to drying at 50° C. for 30 minutes and at 80° C. for 30 minutes, and was subjected to 5 times of pulsed irradiation at 600 V-50 psec (irradiation interval (off) being 30 seconds) using Pulse Forge3300 manufactured by NovaCentrix. Thereafter, PANAPROTECT (registered trademark) PX50T01A15 (PET film (50 μm thick) provided with a 15 μm-thick adhesive layer on one side, purchased from PANAC Co., Ltd.) was adhered as a transparent protection film.

Subsequently, the Y-electrode drawing lead wiring pattern, and the Y-electrode pattern shown in FIG. 8 were printed on the rear face of the Lumirror film, using the same ink, under the same conditions, and by the same treatment method, and a transparent protection film was adhered thereon. The Y-electrode pattern was arranged so that the rhombi thereof do not overlap the rhombi of the X-electrode pattern, and were arranged between the rhombi of the X-electrode pattern.

The resistance value of the produced transparent conductive substrate was measured by Digital Multimeter PC500a manufactured by Sanwa Electric Instrument Co., Ltd. As a result, it was confirmed that the resistance value of the X-electrode pattern shown in FIG. 7 in the X-axis direction (right/left direction in FIG. 7) was in the range of 4 kΩ to 6 kΩ, the resistance value of the Y-electrode pattern shown in FIG. 8 in the Y-axis direction (upper/lower direction in FIG. 8) was in the range of 6 kΩ to 8 kΩ, and the resistance between the electrodes (between upper and lower patterns in FIG.7, between right and left patterns in FIG. 8) was infinity (no short-circuit was occurred between the electrodes). The light transmittance in the visible light range (400 to 800 nm) measured as a reference value showing transparency, using an ultraviolet-visible-near infrared spectrophotometer Jasco V-570 manufactured by JASCO Corporation was 82%.

### Example 2

According to the method of Example 1, first, the X-electrode drawing lead wiring pattern was printed, and thereafter, X-electrode pattern was printed using the transparent conductive pattern forming ink containing the silver nanowire, which was then, subjected to drying and photoirradiation. Thereafter, GA4100 RL-A thick medium manufactured by Jujo Chemical Co., Ltd., was printed thereon as a transparent protection overcoat resin, and cured by photoirradation at 150 V-500 μsec, using Pulse Forge 3300 manufactured by NovaCentrix.

Subsequently, the Y-electrode drawing lead wiring pattern, and the Y-electrode pattern shown in FIG. 8 were printed on the rear face of the Lumirror film, using the same ink, under the same conditions, and by the same treatment method, and a transparent protection overcoat resin used above was printed and cured thereon. The Y-electrode pattern was arranged so that the rhombi thereof do not overlap the rhombi of the X-electrode pattern, and were arranged between the rhombi of the X-electrode pattern.

The resistance value of the produced transparent conductive substrate was measured by Digital Multimeter PC500a manufactured by Sanwa Electric Instrument Co., Ltd. As a result, it was confirmed that the resistance value of the X-electrode pattern shown in FIG. 7 in the X-axis direction (right/left direction in FIG. 7) was in the range of 4 kΩ to 6 kΩ, the resistance value of the Y-electrode pattern shown in FIG. 8 in the Y-axis direction (upper/lower direction in FIG. 8) was in the range of 6 kΩ to 8 kΩ, and the resistance between the electrodes (between upper and lower patterns in FIG.7, between right and left patterns in FIG. 8) was infinity (no short-circuit was occurred between the electrodes). The light transmittance in the visible light range (400 to 800 nm) measured as a reference value showing transparency, using an ultraviolet-visible-near infrared spectrophotometer Jasco V-570 manufactured by JASCO Corporation was 85%.

As describe above, the transparent conductive substrate and the production method therefor according to the present disclosure are suitable for an electrostatic capacitance touch panel, and can be applied various technologies for producing transparent wiring, transparent electrodes by printing, such as a touch switch, a RFID antenna, etc.

1. A transparent conductive substrate production method comprising,
a step for forming an electrode drawing lead wiring pattern by printing with a conductive paste, on at least one main face of a transparent substrate,
an electrode printing step for printing an electrode pattern to be connected to the electrode drawing lead wiring pattern, with a transparent conductive pattern forming ink containing metal nanowires or metal nanoparticles, and shape-holding material,
an electrode drying step for drying the electrode pattern, and
an electrode sintering step for subjecting the dried electrode pattern to pulsed light irradiation to sinter the metal nanowires or the metal nanoparticles.

2. A transparent conductive substrate production method according to claim 1, wherein a first electrode drawing lead wiring pattern and a first electrode pattern are formed on one main face of the transparent substrate, and a second electrode drawing lead wiring pattern and a second electrode pattern are formed on the other main face of the transparent substrate.

3. A transparent conductive substrate production method according to claim 1, comprising,
a step for preparing a first transparent substrate provided on one main face thereof with a first electrode drawing lead wiring pattern and a first electrode pattern,
a step for preparing a second transparent substrate provided on one main face thereof with a second electrode drawing lead wiring pattern and a second electrode pattern, and
a step for combining the first transparent substrate and the second transparent substrate with a third transparent substrate therebetween, so that the faces provided the electrode patterns are opposed to each other.

4. A transparent conductive substrate production method according to claim 1, wherein the shape-holding material has a molecular weight in the range of 100 to 500, and has a viscosity of 1.0×10³ to 2.0×10⁶ mPa·s at 25° C.

5. A transparent conductive substrate production method according to claim 1, wherein the electrode sintering step is performed by a combination of pulsed light irradiation and heating.

6. A transparent conductive substrate production method according to claim 1, wherein after the electrode sintering step, the method comprises a protection film adhering step for adhering a transparent protection film, or a step for printing and curing a transparent protection overcoat resin.

7. A transparent conductive substrate production method according to claim 1, wherein each of the above steps is performed by roll-to-roll.

8. A transparent conductive substrate formed by a transparent conductive substrate production method according to claim 1.

9. A transparent conductive substrate comprising a first electrode pattern, a second electrode pattern, and a transparent insulation layer, the transparent insulation layer being located between the first electrode pattern and the second electrode pattern, and the first electrode pattern and the second electrode pattern being formed by sintered metal.

10. A transparent conductive substrate according to claim 9, wherein transparent insulation layer is a transparent film, wherein the first electrode pattern is formed on a first main face of the transparent film, the second electrode pattern is formed on a second main face of the transparent film, and each of the first electrode pattern and the second electrode pattern is further covered with a transparent protection film or a transparent protection overcoat resin.

11. A transparent conductive substrate according to claim 9, wherein the transparent insulation layer is a third transparent film provided on its both main faces with a transparent adhesive layer, the first electrode pattern is formed on one main face of the first transparent film, the second electrode pattern is formed on one main face of the second transparent film, and the first transparent film and the second transparent film are stacked on the third transparent film so that the first electrode pattern and the second electrode pattern are opposed to each other.

12. An electrostatic capacitance touch panel provided with a transparent conductive substrate according to claim 8, on the front face of a display panel of an electronic device.
